(19) United States
(12) Patent Application Publication
(10) Pub. No.: US 2012/0080770 A1
(43) Pub. Date: Apr. 5, 2012

(54) Transformer Arrangement

(76) Inventor: Uwe Wahl, Munich (DE)

(21) Appl. No.: 12/895,430

(22) Filed: Sep. 30, 2010

(51) Int. Cl. H01L 29/66; H01L 21/02

(52) U.S. Cl. 257/531; 438/107; 257/E29.166; 257/E21.022

(57) ABSTRACT

A transformer arrangement and a method for producing a transformer arrangement is disclosed.

### TECHNICAL FIELD

Embodiments of the present invention relate to a transformer arrangement, in particular an integrated transformer arrangement, and in particular, a transformer arrangement for a signal transmission between electronic circuits.

### BACKGROUND

Transformer arrangements, in particular integrated transformer arrangements, can be used to transmit signals or information between electronic circuits of different voltage domains, i.e., between electronic circuits which have different reference potentials and that are galvanically decoupled.

There is a need to provide an integrated transformer arrangement which has a small size, can be operated at a low power consumption, and is robust against noise.

### SUMMARY OF THE INVENTION

A first aspect relates to a transformer arrangement that includes a first semiconductor body with a first surface and a second surface and a second semiconductor body with a first surface and a second surface. The first semiconductor body is arranged on the first semiconductor body such that the first surface of the first semiconductor body faces the second surface of the second semiconductor body. A transformer with a first winding and a second winding is inductively coupled. The first winding is arranged in the region of the first surface of the first semiconductor body. The second winding is arranged in the region of the first surface of the second semiconductor body. The second semiconductor body includes a first void arranged adjacent to the second winding.

A second aspect relates to a method for forming a transformer arrangement. A first semiconductor arrangement is provided with a first semiconductor body comprising a first surface and a second surface. A first winding is arranged in the region of the first surface of the first semiconductor body. A second semiconductor arrangement is provided with a second semiconductor body comprising a first surface and a second surface. A second winding is arranged in the region of the first surface of the second semiconductor body. A first void is formed in the second semiconductor body adjacent to the second winding. The second semiconductor arrangement is mounted on top of the second semiconductor arrangement such that the first surface of the first semiconductor body faces the second surface of the second semiconductor body.

A third aspect relates to a transformer arrangement that includes a first semiconductor body with a first surface and a second surface and a second semiconductor body with a first surface and a second surface. The first semiconductor body is arranged on the first semiconductor body such that the first surface of the first semiconductor body faces the second surface of the second semiconductor body. A transformer with a first winding and a second winding is inductively coupled. The first winding is arranged in the region of the first surface of the first semiconductor body. The second winding is arranged in the region of the first surface of the second semiconductor body. The second semiconductor body has a thickness of less than 50 μm.

A fourth aspect relates to a method for forming a transformer arrangement. A first semiconductor arrangement is provided with a first semiconductor body comprising a first surface and a second surface. A first winding is arranged in the region of the first surface of the first semiconductor body. A second semiconductor arrangement is provided with a second semiconductor body comprising a first surface and a second surface. A second winding is arranged in the region of the first surface of the second semiconductor body. The second semiconductor is thinned to a thickness of less than 50 μm. The second semiconductor arrangement is mounted on top of the second semiconductor arrangement such that the first surface of the first semiconductor body faces the second surface of the second semiconductor body.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a first embodiment of a transformer arrangement which includes two semiconductor bodies;

FIG. 2 illustrates a vertical cross section through the transformer arrangement of FIG. 1 in a section-plane A-A;

FIG. 3 illustrates an equivalent circuit diagram of the transformer arrangement;

FIG. 4 illustrates a further embodiment of a transformer arrangement which includes two semiconductor bodies, wherein integrated circuits are integrated in the semiconductor bodies;

FIG. 5 illustrates a further embodiment of a transformer arrangement which includes two semiconductor bodies;

FIG. 6, which includes FIGS. 6A to 6D, illustrates an embodiment of a method for producing a transformer arrangement; and

FIG. 7 illustrates another embodiment of a transformer arrangement which includes two semiconductor bodies.

### DETAILED DESCRIPTION OF ILLUSTRATIVE EMBODIMENTS

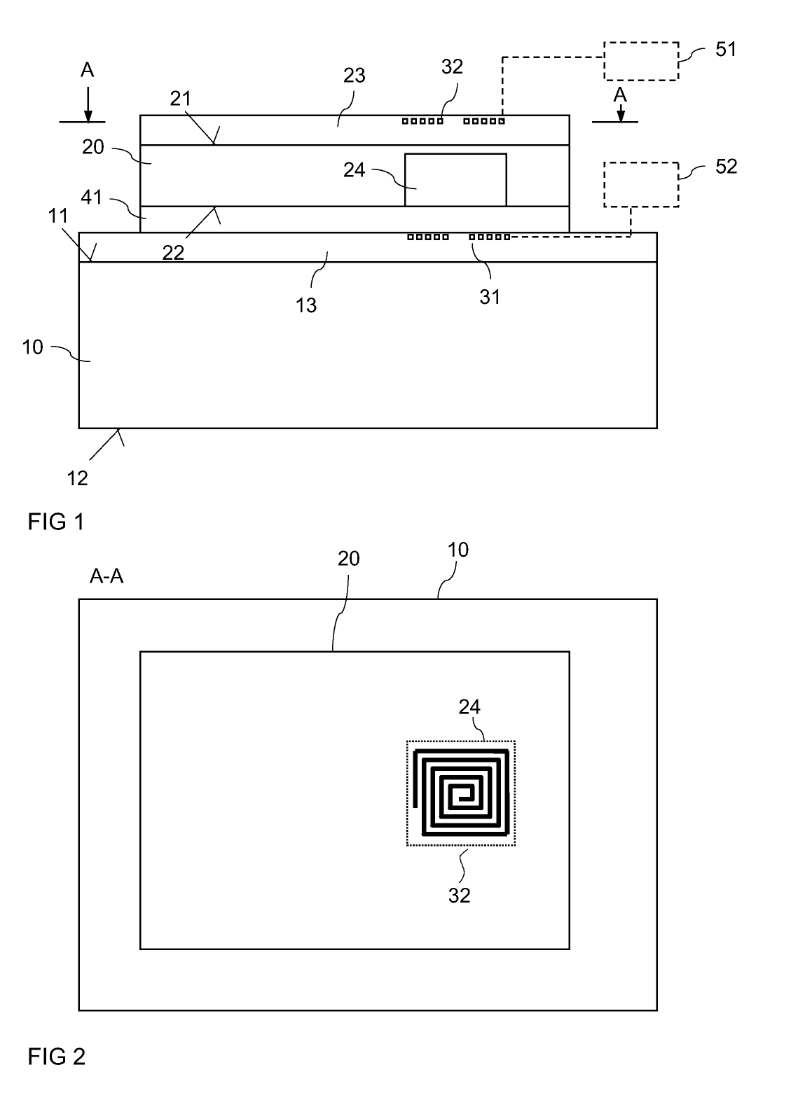

FIG. 1 illustrates a vertical cross section through a transformer arrangement according to a first embodiment. The transformer arrangement includes two semiconductor arrangements. A first semiconductor arrangement with a first semiconductor body 10 includes a first surface 11 and a second surface 12 that are arranged opposite to one another. A second semiconductor arrangement with a second semiconductor body 20 includes a first surface 21 and a second surface 22 that are arranged opposite to one another. The first semiconductor arrangement further includes a first winding 31 which is arranged in the region of the first surface 11 of the first semiconductor body 10, and the second semiconductor arrangement further includes a second winding 32 of a transformer which is arranged in a region of the first surface 21 of the second semiconductor body 20. In the embodiment illustrated in FIG. 1, the first winding 31 is arranged or integrated in a first dielectric layer 13 which is arranged on top of the first surface 11 of the first semiconductor body 10, and the second winding 32 is arranged or integrated in a second dielectric layer 23 which is arranged on top of the first surface 21 of the second semiconductor body 20. However, implementing the first and second windings in dielectric layers is only an example. These windings could also be implemented in the semiconductor bodies 10, 20 below the first surfaces 11, 21.

In the transformer arrangement the first and second semiconductor bodies 10, 20 or semiconductor arrangements are arranged one upon the other, wherein the second semiconductor arrangement with the second semiconductor body 20 is arranged on top of the first semiconductor arrangement with the first semiconductor body 10. In the embodiment illustrated in FIG. 1, the second semiconductor arrangement is arranged on the first semiconductor arrangement such that the first surface 11 of the first semiconductor body 10 faces the second surface 22 of the second semiconductor body 20, wherein the first dielectric layer 13 is arranged between these two surfaces 11, 22. Optionally, an attachment layer 41, which is also known as die attach is arranged between the first and second semiconductor arrangements. This attachment layer 41 attaches the second semiconductor arrangement to the first semiconductor arrangement. The attachment layer 41 includes, for example, a glue, a solder, an adhesive foil or sheet. It is also possible to bond the second semiconductor body 20 to the first semiconductor body 10.

The second semiconductor arrangement is mounted on the first semiconductor arrangement such that the first and second windings 31, 32 are arranged distant from one another in a vertical direction of the transformer arrangement, and at least partially overlap in a horizontal direction of the transformer arrangement. The “vertical direction” of the transformer arrangement is a direction which is perpendicular to the surfaces 11, 12, 21, 22 of the first and second semiconductor bodies 10, 20, and a “horizontal direction” is a direction parallel to these surfaces of the first and second semiconductor bodies 10, 20.

The first and second windings 31, 32 are inductively coupled and form a transformer. In the embodiment illustrated in FIG. 1 these windings 31, 32 are planar windings, which means that each of these windings is formed by a spiral-shaped conductor that is arranged in one plane. The conductors which form the first and second windings 31, 32 include an electrically conductive material, e.g., a metal, such as copper, aluminum or titanium, or a highly doped polycrystalline semiconductor material, such as highly doped polysilicon. By virtue of the inductive coupling between the first and second windings 31, 32 the transformer with the first and second windings 31, 32 can be used to transmit data between a first circuit 51 (illustrated in dashed lines) connected to the first winding 31 and a second circuit 52 (illustrated in dashed lines) connected to the second winding 32. One of these circuits is implemented as a sender (transmitter) circuit, while the other circuit is implemented as a receiver circuit. It should be noted, that each of these circuits can have a transmitter and receiver function, wherein at each time one of these circuits acts as a transmitter while the other circuits acts as a receiver. The first and second circuits 51, 52 can be implemented in a conventional manner, so that no further explanations are required in this regard.

The signal transmission performance of the transformer arrangement is dependent on the inductive coupling factor. This inductive coupling factor is dependent on different parameters, like the distance between the first and second windings 31, 32 in the vertical direction, the overlap of the first and second windings 31, 32 in the horizontal direction, and the type of material arranged between the first and second windings 31, 32. The inductive coupling factor increases when the distance between the first and second windings 31, 32 in the vertical direction decreases, and when the overlap between the first and second windings 31, 32 in the horizontal direction increases.

According to one embodiment the first and second windings 31, 32 completely overlap in the horizontal direction. According to one embodiment, one of the first and second windings 31, 32 is larger in the horizontal plane than the other one of the first and second windings 31, 32. Implementing one of the windings 31, 32 with larger dimensions than the other of the windings, i.e., with a larger diameter than the other winding, reduces the influence of production tolerances in positioning the second semiconductor arrangement on top of the first semiconductor arrangement such that the “smaller” winding is completely overlapped by the “larger” winding.

In order to increase the coupling factor the second semiconductor body 20 has a reduced thickness of lower than 50 μm, lower than 20 μm, lower than 10 μm, or even lower than 5 μm. The reduced thickness of the second semiconductor body 20 is, for example, obtained by removing sections of the second semiconductor body 20 in the region of its second surface 22 after producing the second winding 32 and before mounting the second semiconductor arrangement on top of the first semiconductor arrangement. A method for removing sections of the second semiconductor body 20 or for thinning the second semiconductor body 20 include, for example, chemical and/or mechanical etching or polishing processes, like a CMP process (CMP=chemical-mechanical-polishing).

Alternatively or additionally to the second semiconductor body 20 having a reduced thickness of less than 50 μm, the second semiconductor body 20 includes a void 24 adjacent to the second winding 32 and between the first and second windings 31, 32. This void 24 is filled with a dielectric material, like air, an oxide, a nitride, an imide, or porous silica. A thickness of the second semiconductor body 20 at the bottom of the void 24, i.e., a thickness between the first void 24 and the first surface 21 of the first semiconductor body 10, is, for example, between 0 (or several nanometers (nm)) and several micrometers (μm), like 1 to 3 μm.

FIG. 2 illustrates a top view on the transformer arrangement of FIG. 1. As it can be seen, the second semiconductor arrangement has smaller dimensions in the horizontal plane than the first semiconductor arrangement. However, this is only an example. The first and second semiconductor arrangements could also have identical dimensions in the horizontal plane. For a better understanding, a top view on the second winding 32 is illustrated in FIG. 2. This second winding 32 is implemented as a planar winding. It should be noted in this connection that the first winding 31 can be implemented like the second winding 32.

The winding 32 illustrated in FIG. 2 basically has winding sections with a rectangular geometry. However, this is only an example. The first and second windings 31, 32 can be implemented with winding sections having a geometry other than a rectangular geometry as well, like winding sections with a hexagonal, an octagonal or a circular geometry.

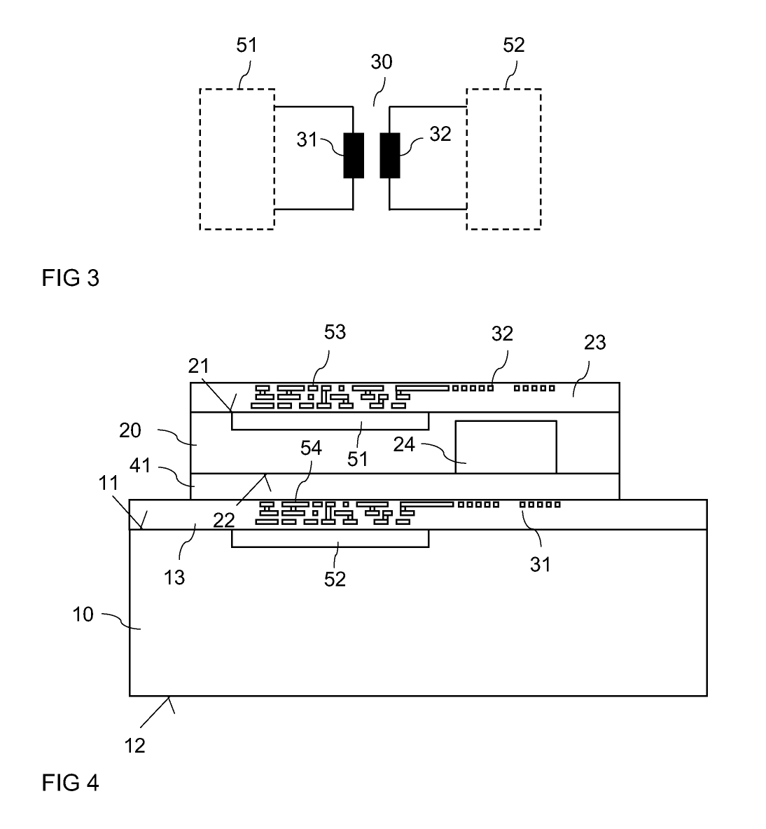

FIG. 3 illustrates an electronic circuit diagram of the transformer arrangement according to FIGS. 1 and 2. Referring to the explanation provided herein above, the first and second windings 31, 32 form a transformer 30 which is part of a signal transmission path between first and second electronic circuits 51, 52. One of these circuits acts as a transmitter which transmits data via the transformer 30, and one of these circuits acts as a receiver which receives the transmitted data from the transformer 30. The transformer is, in particular a coreless transformer, i.e., a transformer which does not include a transformer core.

Referring to FIG. 4, which illustrates a vertical cross section through a transformer arrangement according to a further embodiment, the first electronic circuit 51 which is connected to the first winding 31 can be integrated in the first semiconductor body 10, and the second electronic circuit 52 which is connected to the second winding 32 can be integrated in the second semiconductor body 20. These electronic circuits 51, 52 are only schematically illustrated in FIG. 4 and can be implemented like conventional integrated circuits with integrated electronic devices, like transistors, diodes, and resistors.

In the embodiment illustrated in FIG. 4, the first electronic circuit 51 is connected to the first winding 31 via a first wiring arrangement 54, wherein the first wiring arrangement 54 also interconnects the individual devices of the first electronic circuit 51. The second electronic circuit 52 is connected to the second winding 32 via a second wiring arrangement 53 which is arranged in the second dielectric layer 23, wherein the second wiring arrangement 53 also interconnects the individual devices of the first electronic circuit 51. The first and second wiring arrangements 53, 54 can be implemented like conventional wiring arrangements with conductors arranged in different conductor or metallization planes of the first and second dielectric layers 13, 23, wherein conductors in different metallization planes of one wiring arrangement can be interconnected with each other through vias.

FIG. 5 illustrates a vertical cross section through a transformer arrangement according to a further embodiment. This transformer arrangement includes a second void 14 in the first semiconductor body 10 adjacent to the first winding 31. The second void 14, like the first void 24, is filled with a dielectric material, like air, an oxide, a nitride, or imide, or porous silica. This second void 14 filled with a dielectric material helps to reduce eddy currents in the first semiconductor body 10 induced by the first winding 31. Reducing these eddy currents helps to reduce losses and, therefore helps to increase the coil quality (coil Q) of the first winding 31 and, therefore, helps to increase the signal transmission performance.

Referring to FIG. 5, the transformer arrangement with the first and second semiconductor arrangement can be mounted on a carrier 60, like a printed circuit board (PCB), a lead frame, a DCB (direct copper bonding) substrate, etc.

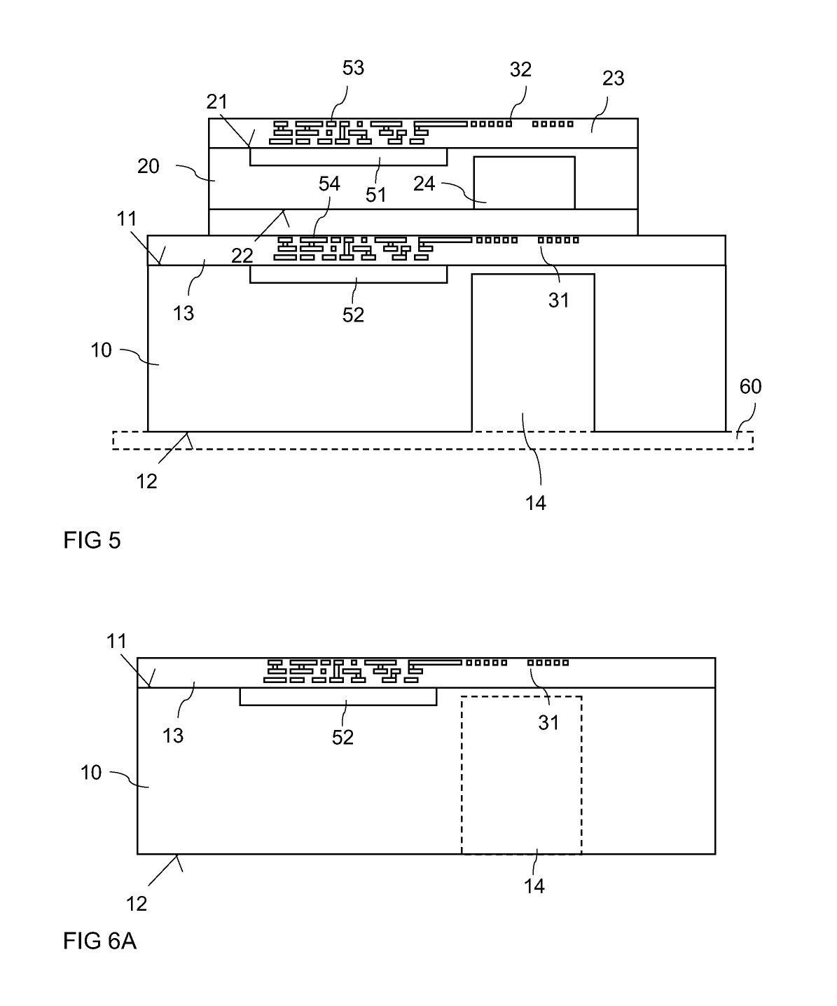

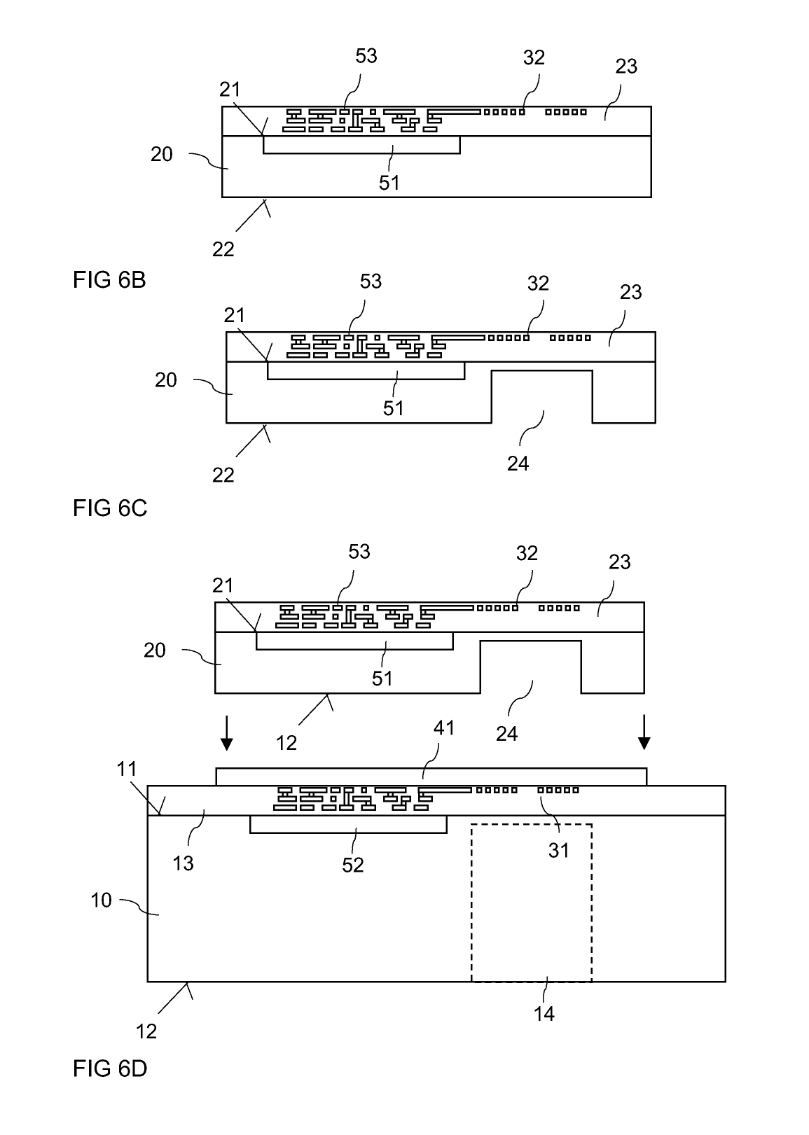

An embodiment of a method for producing a transformer arrangement will now be explained with reference to FIGS. 6A to 6D which illustrate vertical cross sections through the transformer arrangement during the production process. The method illustrated in FIGS. 6A to 6D relates to a method for producing the transformer arrangement according to FIG. 4 or 5. However, this is only an example. The general methods are identical for the production of each of the transformer arrangements explained herein before.

Referring to FIG. 6A the first semiconductor arrangement with the first semiconductor body 10 and the first winding 31 is provided. The first semiconductor arrangement can be produced using conventional method steps is provided. The first semiconductor arrangement can be produced using conventional method steps for producing a semiconductor arrangement with a semiconductor body and a planar winding in a dielectric layer 13 on top of the semiconductor body 10. Optionally, the second void 14 is produced in the first semiconductor body 10. Producing the second void 14 includes, for example, an etching method which anisotropically etches the semiconductor material of the first semiconductor body 10 in a region adjacent to the first winding 31 and starting from the second surface 12 of the first semiconductor body 10.

Referring to FIG. 6B, the second semiconductor arrangement with the second semiconductor body 20 and the second winding 32 is provided in a next method step. This second semiconductor arrangement can be produced using conventional method steps for producing a semiconductor arrangement with a semiconductor body, an optional electronic circuit integrated in the semiconductor body, and a planar winding arranged in a dielectric layer 23 on top of the semiconductor body 20.

Referring to FIG. 6C, the thickness of the second semiconductor body 20 is reduced by removing the semiconductor material of the second semiconductor body 20 in the region of the second surface. Removing semiconductor material of the first semiconductor body 10 in the region of the second surface 22 includes, for example, a polishing process, like a CMP process, or an etching process, like an isotropical etching process. Alternatively or additionally to reducing the thickness of the second semiconductor body 20, the first void 24 is produced in the second semiconductor body 20 adjacent to the second winding 32. Producing the first void 24 includes, for example, an etching method which anisotropically etches the semiconductor material of the second semiconductor body 20 in a region adjacent to the second winding 32 and starting from the second surface 22 of the second semiconductor body 20.

Referring to FIG. 6D the second semiconductor arrangement is then mounted on the first semiconductor arrangement using an optional attachment layer 41. In the embodiment illustrated in FIG. 6D the attachment layer 41 is arranged on the first semiconductor arrangement before mounting the second semiconductor arrangement on top of the first semiconductor arrangement. However, this is only an example. The attachment layer 41 could also be provided on the second surface 22 of the second semiconductor body 20 before the mounting process.

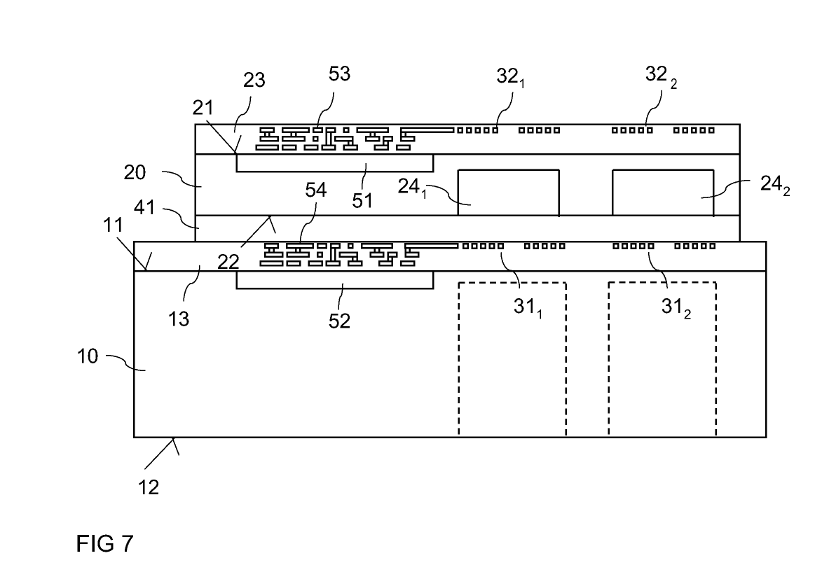

In the embodiments illustrated herein before, the transformer arrangement includes one transformer with one first winding and one second winding. However, this is only an example. The basic principle explained herein above is also applicable to a transformer arrangement with a plurality of transformers, with each of these transformers including a first and a second winding. FIG. 7 schematically illustrates a vertical cross section through a transformer arrangement with two transformers, wherein each of these transformers includes a first winding 31₁, 31₂ arranged in the region of the first surface 11 of the first semiconductor body 10, and a second winding 32₁, 32₂ arranged in the region of the first surface 21 of the second semiconductor body 20. The first and second windings of each of these transformers at least partially overlap, and are arranged distant from one another in the vertical direction of the transformer arrangement. Everything which has been put forward in connection with the transformer explained in connection with FIGS. 1 to 6 applies to each of the first and second transformers illustrated in FIG. 7 accordingly. The second semiconductor body 20 optionally includes first voids 24₁, 24₂ adjacent to the second windings 32₁, 32₂. According to one embodiment, the second semiconductor body 20 includes only one void which overlaps each of the second windings 32₁, 32₂ in the horizontal plane. Optionally, second voids are arranged in the first semiconductor body 10 adjacent to the first windings 31₁, 31₂, wherein according to one embodiment only one void is provided in the first semiconductor body 10 which overlaps each of the first windings 31₁, 31₂.

The transformers with the first and second windings 31₁, 31₂, 32₁, 32₂ can be connected to sender and receiver circuits 51, 52, wherein these circuits can be implemented in the first and second semiconductor bodies. Of course individual sender and receiver circuits can be provided for each of the transformers.

Finally it should be mentioned that features which have been explained in connection with one embodiment can be combined with features of each of the other embodiments even if this is not explicitly stated herein before.

What is claimed is:

1. A transformer arrangement, comprising:
a first semiconductor body with a first surface and a second surface;
a second semiconductor body with a first surface and a second surface, wherein the first semiconductor body is arranged on the second semiconductor body such that the first surface of the first semiconductor body faces the second surface of the second semiconductor body; and
a transformer with a first winding and a second winding which are inductively coupled, wherein the first winding is arranged in a region of the first surface of the first semiconductor body, and the second winding is arranged in a region of the first surface of the second semiconductor body;
wherein the second semiconductor body comprises a first void arranged adjacent to the second winding.

2. The transformer arrangement of claim 1, wherein the second semiconductor body has a thickness of less than 50 μm.

3. The transformer arrangement of claim 1, wherein the first void is implemented as a trench that extends from the second surface of the second semiconductor body.

4. The transformer arrangement of claim 1, further comprising:
a second void arranged in the first semiconductor body adjacent to the first winding.

5. The transformer arrangement of claim 4, wherein the second void is implemented as a trench that extends from the second surface of the first semiconductor body.

6. The transformer arrangement of claim 1, wherein the first void comprises a dielectric material.

7. The transformer arrangement of claim 4, wherein the second void comprises a dielectric material.

8. The transformer arrangement of claim 1, further comprising:
a first dielectric layer arranged on the first surface of the first semiconductor body, wherein the first winding is arranged in the first dielectric layer.

9. The transformer arrangement of claim 1, further comprising:
a second dielectric layer arranged on the first surface of the second semiconductor body, wherein the second winding is arranged in the second dielectric layer.

10. The transformer arrangement of claim 1 wherein at least one of the first and second windings is a planar winding.

11. The transformer arrangement of claim 1, further comprising:
a first integrated circuit integrated in the first semiconductor body and connected to the first winding.

12. The transformer arrangement of claim 1, further comprising:
a second integrated circuit integrated in the second semiconductor body and connected to the second winding.

13. The transformer arrangement of claim 1, further comprising a connection layer arranged between the first and second semiconductor bodies.

14. A method for forming a transformer arrangement, the method comprising:
providing a first semiconductor arrangement with a first semiconductor body comprising a first surface and a second surface, and with a first winding arranged in a region of the first surface of the first semiconductor body;
providing a second semiconductor arrangement with a second semiconductor body comprising a first surface and a second surface, and with a second winding arranged in a region of the first surface of the second semiconductor body;
forming a first void in the second semiconductor body adjacent to the second winding; and
attaching the second semiconductor arrangement and the first semiconductor arrangement such that the first surface of the first semiconductor body faces the second surface of the second semiconductor body.

15. The method of claim 14, further comprising:
forming a second void in the first semiconductor body adjacent to the second winding before attaching the second semiconductor arrangement and the first semiconductor arrangement.

16. The method of claim 14, wherein forming the first void comprises forming a trench in the second semiconductor body, the trench extending from the second surface into the second semiconductor body.

17. The method of claim 14, further comprising:
at least partially filling the first void with a dielectric material.

18. The method of claim 14, wherein attaching the second semiconductor arrangement and the first semiconductor arrangement comprises a soldering or gluing process.

19. A transformer arrangement, comprising:
a first semiconductor body with a first surface and a second surface;
a second semiconductor body with a first surface and a second surface, wherein the first semiconductor body is arranged on the second semiconductor body such that the first surface of the first semiconductor body faces the second surface of the second semiconductor body; and
a transformer with a first winding and a second winding which are inductively coupled, wherein the first winding is arranged in a region of the first surface of the first semiconductor body, and the second winding is arranged in a region of the first surface of the second semiconductor body;
wherein the second semiconductor body has a thickness of less than 50 μm.

20. The transformer arrangement of claim 19, wherein the second semiconductor body has a thickness of less than 10 μm.

21. The transformer arrangement of claim 19, wherein the second semiconductor body comprises a first void arranged adjacent to the second winding.

22. A method for forming a transformer arrangement, the method comprising:
providing a first semiconductor arrangement with a first semiconductor body comprising a first surface and a second surface, and with a first winding arranged in a region of the first surface of the first semiconductor body;
providing a second semiconductor arrangement with a second semiconductor body comprising a first surface and a second surface, and with a second winding arranged in a region of the first surface of the second semiconductor body;
thinning the second semiconductor body to a thickness of less than 50 μm; and
mounting the second semiconductor arrangement on top of the first semiconductor arrangement such that the first surface of the first semiconductor body faces the second surface of the second semiconductor body.

23. The method of claim 22, wherein the thinning comprises thinning the second semiconductor body to a thickness of less than 10 μm.

24. The method of claim, 22, further comprising:
forming a first void in the second semiconductor body adjacent to the second winding.
